(19) United States
(12) Patent Application Publication
(10) Pub. No.: US 2024/0313080 A1
(43) Pub. Date: Sep. 19, 2024

(54) TWO-DIMENSIONAL SEMICONDUCTOR DEVICE AND ELECTRODE USED THEREIN

(71) Applicant: National Tsing Hua University, Hsinchu City (TW)

(72) Inventors: Po-Wen Chiu, Hsinchu City (TW); SunZen Chen, Hsinchu City (TW); ChiChun Cheng, Hsinchu City (TW)

(73) Assignee: National Tsing Hua University, Hsinchu City (TW)

(21) Appl. No.: 18/333,567

(22) Filed: Jun. 13, 2023

(30) Foreign Application Priority Data
Mar. 13, 2023 (TW) 112109159

(51) Int. Cl. H01L 29/47; H01L 29/24; H01L 29/76

(52) U.S. Cl. CPC H01L 29/47; H01L 29/24; H01L 29/7606

(57) ABSTRACT

A two-dimensional semiconductor device and an electrode used therein are provided. The material of the contact electrode is a semi-metal alloy, and the semi-metal alloy is composed of several semi-metal elements or at least one semi-metal element and an alloy material thereof. The two-dimensional semiconductor device includes a substrate, a two-dimensional semiconductor material layer formed on the substrate, and electrodes formed on the two-dimensional semiconductor material layer. The electrodes include the contact electrode and the metal electrode, and the contact electrode is between the metal electrode and the two-dimensional semiconductor material layer, so that the semi-metal alloy forms a space gap slightly smaller than a Van der Waals distance on top of the two-dimensional semiconductor to ensure the stability of the structure while preventing/minimizing the coupling of outer orbital electrons between the two-dimensional semiconductor and the electrode.

### CROSS-REFERENCE TO RELATED APPLICATION

This application claims the priority benefit of Taiwan application serial no. 112109159, filed on Mar. 13, 2023. The entirety of the above-mentioned patent application is hereby incorporated by reference herein and made a part of this specification.

### BACKGROUND

### Technical Field

The disclosure relates to a two-dimensional semiconductor device technique, and in particular to a two-dimensional semiconductor device and an electrode used therein.

### Description of Related Art

Two-dimensional material is a crystalline material composed of a single layer or a few layers of atoms. Its energy gap may be adjusted with changes in chemical composition and atomic layer number. Hence, it can be used to improve the performance of electronic devices, such as light-emitting devices. Furthermore, two-dimensional materials have also been applied to semiconductor devices recently, and the channel thickness of field effect transistors is expected to be further reduced to the atomic scale.

Reducing the impedance between the metal/semiconductor interface to improve the efficiency of the device has always been an effective method to improve the efficiency of the device. For a two-dimensional material semiconductor device using transition metal dichalcogenide (TMD), the interface between the semiconductor and the metal will generate additional gap states (metal-induced gap state, MIGS) on the energy gap at the interface due to the metallization of the semiconductor. These induced vacant gap states will trap carriers flowing through the interface, resulting in the Fermi level pinning (FLP) effect, causing the formation of Schottky contacts on the metal-semiconductor interface, which will cause inevitable and undesirable contact impedance.

### SUMMARY

The disclosure provides an electrode for a two-dimensional semiconductor device, which may not only improve the properties of the device, but also adjust its Fermi level to be the same as or close to that of the semiconductor via altering its alloy composition or alloy ratio. Therefore, more kinds of semiconductor materials can have the properties of stable interface and ohmic contact.

The disclosure provides a two-dimensional semiconductor device, which can improve the electrical properties of the device, such as low subthreshold swing (SS), high carrier mobility, and improved junction contact resistance.

An electrode for a two-dimensional semiconductor device of the disclosure includes a contact electrode and a metal electrode formed thereon. The contact electrode is made of a semi-metal alloy including several semi-metal elements or at least one semi-metal element and its alloy. And the Fermi surface of the semi-metal alloy is adjusted by altering its alloy ratio, hence as the contact electrode is in contact with the two-dimensional semiconductor, only a tiny amount of gap states (such as gap states less than leV or even zero) is generated on the energy gap at the interface to reduce the Schottky energy barrier. At the same time, a space gap slightly smaller than a Van der Waals distance is created on top of the two-dimensional semiconductor to ensure the stability of the structure while preventing or minimizing the coupling of outer orbital electrons between the metal electrode and the two-dimensional semiconductor.

In an embodiment of the disclosure, the semi-metal element includes antimony (Sb), bismuth (Bi), or tin (Sn).

In an embodiment of the disclosure, the semi-metal alloy is an antimony-bismuth alloy or a bismuth-aluminum alloy.

In an embodiment of the disclosure, the antimony content in the antimony-bismuth alloy is between 10 a % and 84 a %.

In an embodiment of the disclosure, the Fermi surface of the semi-metal alloy may be matched with that of the Fermi surface of the n-type or p-type two-dimensional semiconductor to achieve the lowest Schottky energy barrier.

In an embodiment of the disclosure, the metal electrode includes platinum (Pt), gold (Au), aluminum (Al), titanium (Ti), or chromium (Cr).

A two-dimensional semiconductor device of the disclosure includes a substrate, a two-dimensional semiconductor layer, and multiple electrodes. A two-dimensional semiconductor layer is formed on the substrate, and the electrodes are formed on the two-dimensional semiconductor layer. The electrodes include a contact electrode and a metal electrode, and the contact electrode is set not only between the metal electrode and the two-dimensional semiconductor layer to avoid direct contact of the two-dimensional material and the metal electrode, but also creates a space gap slightly smaller than a Van der Waals distance between the metal electrode and the two-dimensional semiconductor layer to further ensure the stability of the structure and prevent/minimize the coupling of outer orbital electrons between the metal electrode and the two-dimensional semiconductor layer.

In an embodiment of the disclosure, the material of the two-dimensional semiconductor layer includes, but is not limited to, tungsten disulfide (WS₂), molybdenum disulfide (MoS₂), tungsten diselenide (WSe₂), molybdenum ditelluride (MoTe₂), tungsten ditelluride (WTe₂), or molybdenum diselenide (MoSe₂).

Based on the above, in the electrode for the two-dimensional semiconductor device of the disclosure, the semi-metal alloy is used as the contact electrode in contact with the two-dimensional semiconductor layer, which can not only reduce the generation of additional gap states (metal-induced gap state; MIGS) at the semiconductor-metal interface, but also change the Fermi surface of the semi-metal alloy appropriately by adjusting the ratio of the alloy, thereby reducing or eliminating the Schottky energy barrier caused by the Fermi level pinning (FLP) effect at the metal-semiconductor interface. Compared with the contact electrode using a single element electrode (single metal or single semi-metal), the use of the semi-metal alloy of the disclosure may not only adjust the Fermi level of the contact electrode, so that the Fermi level thereof can better match the Fermi level of the semiconductor, but also effectively improve the properties of the device, such as a transistor, because of the matching of energy levels.

To make the aforementioned more comprehensible, several embodiments accompanied by drawings are described in detail as follows.

### BRIEF DESCRIPTION OF THE DRAWINGS

FIG. 1 is a schematic diagram of a two-dimensional semiconductor device according to an embodiment of the disclosure.

FIG. 2 is a diagram of the electronic density of state of different ratios of antimony-bismuth alloys and a single semi-metal obtained by using the first-principle calculation.

FIG. 3 is a graph of the on-off current ratio, subthreshold swing, and carrier mobility of the WS₂-FET device of Comparative Examples 1 to 3 and Experimental Example 1.

FIG. 4 is a graph of the on-off current ratio, subthreshold swing, and carrier mobility of the WS₂-FET device of Comparative Examples 2 to 4.

### DESCRIPTION OF THE EMBODIMENTS

An electrode for a two-dimensional semiconductor device of the disclosure at least includes a contact electrode and a metal electrode formed thereon, wherein the material of the contact electrode is a semi-metal alloy, and the semi-metal alloy includes several semi-metal elements or at least one semi-metal element and an alloy material thereof. In an embodiment, the semi-metal element includes antimony (Sb), bismuth (Bi), tin (Sn), and other elements, and the semi-metal alloy refers to a mixture of various semi-metal elements (for example, antimony-bismuth alloy) or an alloy formed of a semi-metal element and an alloy material thereof (for example, bismuth aluminum alloy). In an embodiment, the metal electrode includes platinum (Pt), gold (Au), aluminum (Al), titanium (Ti), chromium (Cr), or other known common electrodes. Since the semi-metal has no (or extremely low) electronic density of state in the Fermi level bandgap, after contact with the two-dimensional semiconductor, only a tiny amount of gap states (such as gap states less than leV or even 0) are produced, so as to reduce the Schottky energy barrier. Therefore, the generation of MIGS can be avoided/reduced, and the phenomenon of FLP can be eliminated/reduced to achieve the purpose of improving the electrical properties of the semiconductor device. However, the energy level properties of a single semi-metal are fixed and cannot be applied to various semiconductor devices (especially when more two-dimensional semiconductor devices will be developed in the future). Therefore, it is necessary to use an alloy to regulate the Fermi level of the semi-metal contact electrode, so as to adjust the energy level mismatch between the metal and the semiconductor and eliminate/improve the FLP at the interface. At the same time, the semi-metal alloy may form a gap that is slightly smaller than the Van der Waals distance above the two-dimensional semiconductor, so as to ensure the stability of the structure while preventing/minimizing the coupling of outer orbital electrons at the interface between the two-dimensional semiconductor and the metal electrode.

The accompanying drawings in the following embodiments are for a more complete description of the embodiments of the disclosure. However, the disclosure may still be implemented in many different forms not limited to the described embodiments. In addition, the relative thicknesses, distances, and positions of various regions or layers may be reduced or enlarged for clarity.

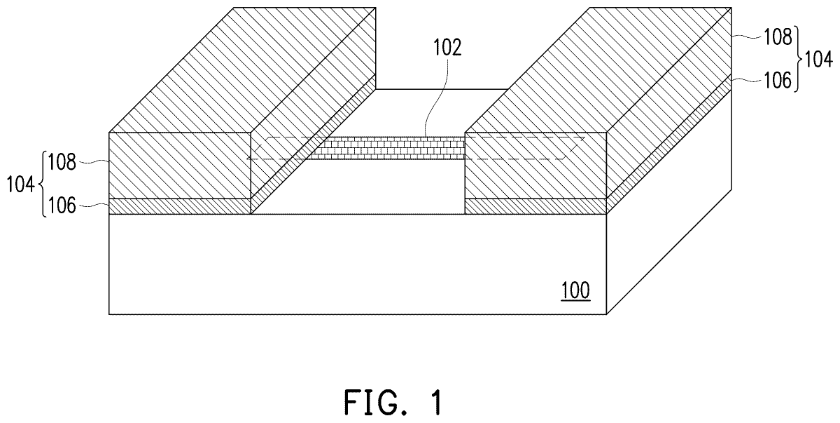

FIG. 1 is a schematic diagram of a two-dimensional semiconductor device according to an embodiment of the disclosure.

Referring to FIG. 1, the two-dimensional semiconductor device of this embodiment includes a substrate 100, a two-dimensional semiconductor layer 102, and multiple electrodes 104. The two-dimensional semiconductor layer 102 is formed on the substrate 100, and the electrode 104 is formed on the two-dimensional semiconductor layer 102, wherein the electrode 104 is the electrode for the two-dimensional semiconductor device described above. Therefore, the electrode 104 includes a contact electrode 106 and a metal electrode 108, and the contact electrode 106 is between the metal electrode 108 and the two-dimensional semiconductor layer 102. The semi-metal alloy used as the contact electrode 106 may form a gap (not shown) that is slightly smaller than the Van der Waals distance above the two-dimensional semiconductor layer 102, so as to ensure the stability of the structure. In detail, the metal electrode 108 is, for example, platinum (Pt), gold (Au), aluminum (Al), titanium (Ti), chromium (Cr), or other known commonly used electrodes. The contact electrode 106 is a semi-metal alloy. In an embodiment, the semi-metal element contained in the contact electrode 106 is at least two elements selected from antimony (Sb), bismuth (Bi), and tin (Sn), such as antimony bismuth alloy (SbBi alloy). The semi-metal alloy refers to the mixture of various semi-metal elements (for example, antimony-bismuth alloy) or an alloy formed by at least one semi-metal element and an alloy material thereof.

The two-dimensional semiconductor layer 102 is usually only a few layers thick and exists in the form of a strong bonding within the same layer, and there is only a weak Van der Waals force between the layers, which may be mechanically or chemically exfoliated into individual and atomically thin layers. In some embodiments, the two-dimensional semiconductor layer 102 may include one or more layers, and the thickness thereof may be between about 0.5 nm and 100 nm. The material of the two-dimensional semiconductor layer 102 includes, but is not limited to, tungsten disulfide (WS₂), molybdenum disulfide (MoS₂), tungsten diselenide (WSe₂), molybdenum ditelluride (MoTe₂), tungsten ditelluride (WTe₂), or molybdenum diselenide (MoSe₂). The two-dimensional semiconductor layer 102 may be used as an active layer of an ultra-thin channel transistor, and tungsten disulfide (WS₂) has the properties of a semiconductor and a direct optical bandgap that may be adjusted in the range of 0.8 eV to 2.0 eV, so WS₂ is a preferred material for the two-dimensional semiconductor layer 102.

Please continue to refer to FIG. 1, if the two-dimensional semiconductor device of this embodiment is a back-gate field-effect transistor (back-gate FET), the substrate 100 may be a silicon/silicon oxide (Si/SiO₂) substrate, wherein silicon is boron-doped silicon with a high doping concentration, and a back gate (not shown) is added on the back of the substrate 100. Silicon oxide in the substrate 100 is located between silicon and the two-dimensional semiconductor layer 102. In addition, if the two-dimensional semiconductor device of this embodiment is a dual-gate field-effect transistor (dual-gate FET), a top gate (not shown) and a gate dielectric layer (such as an oxide layer with a high dielectric constant) in between are added on the front of the back-gate field-effect transistor (that is, on the two-dimensional semiconductor layer 102). The substrate 100 may be a silicon/silicon oxide substrate, wherein silicon is general silicon. In another embodiment, if the two-dimensional semiconductor device is a top-gate field-effect transistor (top-gate FET), the substrate 100 may be a semi-insulating substrate such as a semi-insulating SiC substrate, and a gate dielectric layer and a top gate (not shown) are disposed on the two-dimensional semiconductor layer 102.

Several experimental examples are listed below to verify the implementation effect of the disclosure, but the disclosure is not limited to the following content.

### 1. Preparation of Back-Gate Field Effect Transistor

### 1.1. Growth of Monolayer WS₂ Crystal

Low-pressure chemical vapor deposition (LPCVD) was used, and a sapphire substrate was used as the substrate for growing WS₂.

First, the sulfur powder was placed upstream in a LPCVD furnace tube, and a quartz boat loaded with tungsten oxide powder and sapphire substrate was placed downstream. Then. 200 sccm of argon gas and 20 sccm of hydrogen gas were introduced, and a constant pressure was maintained. Finally, the temperature was raised to 850° C., and WS₂ started to grow.

### 1.2. Transfer of WS₂

A 3% polycarbonate (PC) chloroform solution was used to spin-coat the sapphire substrate grown with WS₂ as a carrier for transferring WS₂.

After peeling off the PC film adhered to WS₂ with water, WS₂ was moved into isopropanol (IPA) and then transferred onto a Si/SiO₂ substrate.

After the transfer, PC/WS₂/SiO₂/Si was put into a chloroform solution for 24 hours to dissolve the outermost PC film, leaving WS₂ with a thickness of about 0.8 nm on the SiO₂/Si substrate. Then, after washing with acetone and IPA, the substrate was placed in a vacuum furnace tube for baking to remove residual moisture, volatile solvents, and polymer materials.

### 1.3. Preparation of Semi-Metal Alloy

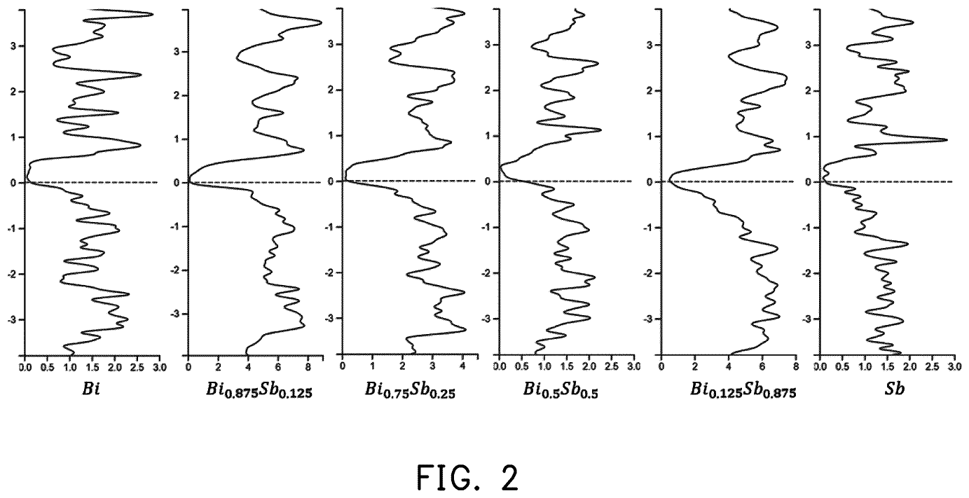

The disclosure is an example of using an antimony-bismuth alloy as a semi-metal alloy. FIG. 2 shows a diagram of the electronic density of the state of different ratios of antimony-bismuth alloys and two semi-metals obtained by using the first-principle calculation, wherein the x-axis represents composition and the y-axis represents E-E_{F} (in eV). It may be seen from FIG. 2 that although different ratios of antimony-bismuth alloys have different Fermi levels, the antimony-bismuth alloys still have semi-metallic properties, that is, there is a significant DOS (density of state?) reduction at the Fermi level (y=0) position.

The preparation manner was to mix specific ratios of antimony and bismuth metal particles, then put the mixture into a small quartz tube, and seal the tube under a vacuum. The sealed quartz tube was placed in a furnace tube, heated to 800° C. at a slow speed, and then maintained for 6 hours to alloy. Then, the temperature was slowly lowered by 1 to 24 hours for the antimony-bismuth alloy to harvest better crystallinity.

### 1.4. Lithography and Metal Evaporation

A digital light processing (DLP) lithography tool was used to generate the designed patterns on the WS₂ active layer. Then, the antimony bismuth alloy and gold (Au) were sequentially deposited onto the SiO₂/Si substrate by thermal evaporation, wherein the antimony-bismuth alloy was preheated for several minutes under 10-7 torr before the deposition to guarantee the uniformity of the deposited alloy film. The thickness of the antimony-bismuth alloy used as the contact electrode was about 20 nm, and the thickness of gold used as the metal electrode was about 60 nm.

After the deposition, a photoresist remover (Remover PG) was used to remove/liftoff the residual photoresist and its on-top antimony-bismuth alloy and gold to obtain the two-dimensional semiconductor device (that is, the WS₂-FET device) as shown in FIG. 1.

### 2. Analysis

### 2.1. Alloy Ratio of Semi-Metallic Alloy

In order to detect the alloy ratio, an Energy-dispersive X-ray spectroscopy (EDS) was used for analysis.

The sample preparation method was to deposit a thickness of about 120 nm of the antimony-bismuth alloy prepared in Step 1.3 above on the sapphire substrate by thermal evaporation. The measurement results of the ratio of specific elements were obtained, so the percentage of the antimony-bismuth alloy was calculated.

### 2.2 Measurement of Electrical Properties

The device properties of the back-gate field effect transistor of Experimental Example 1 were tested to obtain the on/off ratio, subthreshold swing (SS), and carrier mobility of the WS₂-FET device.

### Experimental Example 1

The back-gate field effect transistor was prepared by the above manner, and the obtained antimony-bismuth alloy had an antimony content of 15 a % (atomic percentage) and a bismuth content of 85 a %.

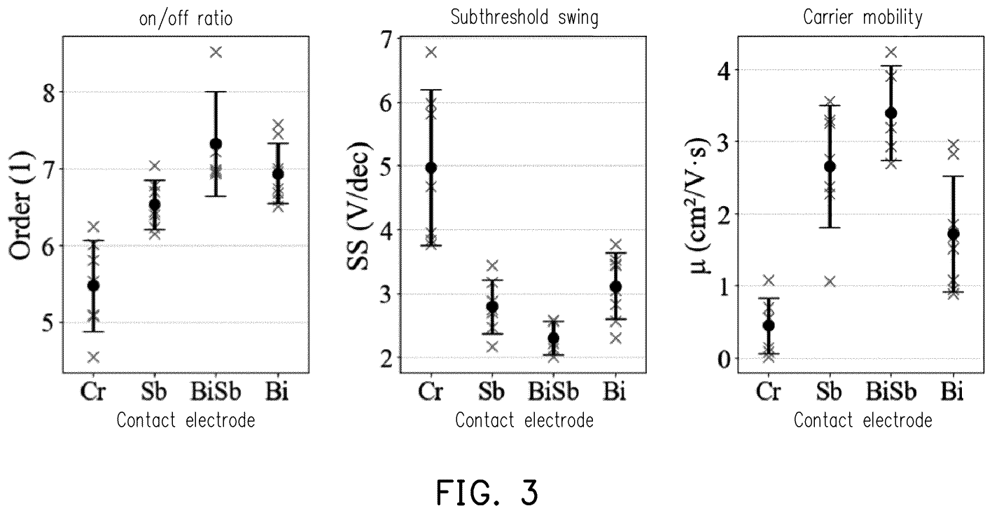

Then, the electrical properties of the WS₂-FET device of Experimental Example 1 were measured, and the results are shown in FIG. 3. In FIG. 3, the antimony-bismuth alloy Bi_{0.85}Sb_{0.15} is used as the contact electrode of the WS₂-FET device and shows a subthreshold swing (SS) lower than 3 V/dec and carrier mobility higher than 3 cm²/V·s.

### Comparative Example 1 to 3

The WS₂-FET devices were fabricated by the same preparation manner as Experimental Example 1, but in Step 1.4, a single metal Cr (Comparative Example 1), a single semi-metal Sb (Comparative Example 2), and a single semi-metal metal Bi (Comparative Example 3), which are conventional adhesive layers used for gold metal electrode, were used as the materials of the contact electrode.

Then, the electrical properties of the WS₂-FET device of Comparative Examples 1 to 3 were measured, and the results are also shown in FIG. 3.

It may be seen from FIG. 3 that the electrical properties of the WS₂-FET devices using the semi-metal alloy as the contact electrode are better than that of the WS₂-FETs using Cr by more than one standard deviation. Moreover, the electrical properties of the WS₂-FET devices using the semi-metal alloy as the contact electrode are also superior to those using the single semi-metal, i.e., showing a higher on-off ratio, lower subthreshold swing, and higher carrier mobility.

### Experimental Example 2 to 4

With the same preparation method as Experimental Example 1, another batch of WS₂-FET devices were fabricated, but the antimony-bismuth alloys were respectively Bi_{0.90}Sb_{0.10} (Experimental Example 2). Bi_{0.68}Sb_{0.32} (Experimental Example 3), and Bi_{0.16}Sb_{0.84} (Experimental Example 4).

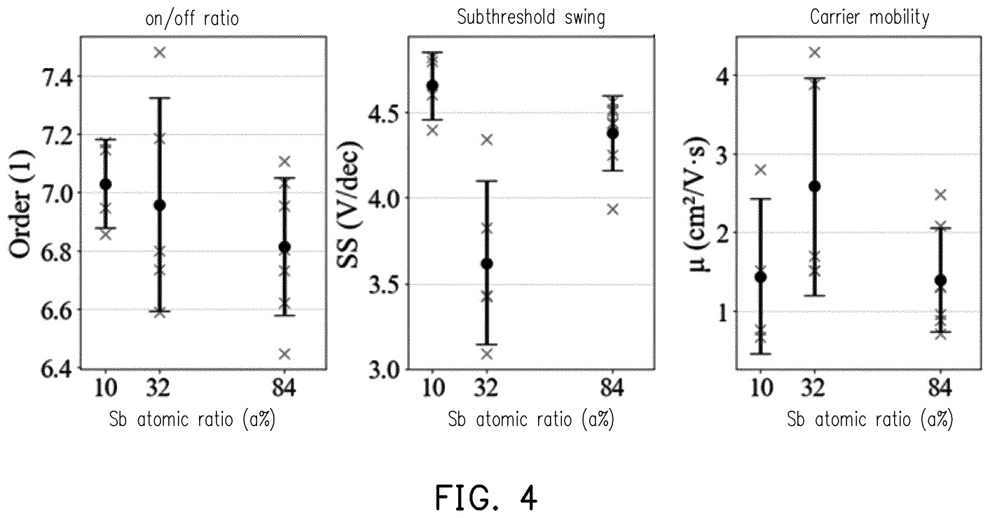

Then, the electrical properties of the WS₂-FET devices of Experimental Examples 2 to 4 were measured, and the results are shown in FIG. 4.

It may be seen from FIG. 4 that the analysis results of the electrical properties of Experimental Example 2 are better than those of Experimental Example 4. It is estimated that the alloy properties of Experimental Example 2 should behave more like bismuth, and its Fermi level is closer to the conduction band of WS₂, so Experimental Example 2 displays better performance. Moreover, the results of Experimental Example 2 and Experimental Example 4 show that the change of the alloy properties is stable and may be simply controlled by the ratio without showing unwanted properties after becoming an alloy. Furthermore, it is also found through experiments that Experimental Example 3 has better results than Experimental Example 2 and Experimental Example 4 in terms of on/off ratio, subthreshold swing, and carrier mobility, so Experimental Example 3 has unexpectedly excellent efficacy.

In summary, the disclosure uses the semi-metal alloys as the electrode for the two-dimensional semiconductor device, which can not only reduce the generation of MIGS, but also linearly change the Fermi level of the semi-metal alloy by adjusting the alloy ratio, so as to form ohmic contact compatible with different two-dimensional semiconductor materials. Therefore, the two-dimensional semiconductor device improved through the contact electrode can not only effectively improve the phenomenon of FLP, but also greatly help the development and application of the two-dimensional semiconductor device.

Although the disclosure has been disclosed above with the embodiments, the embodiments are not intended to limit the disclosure. Those skilled in the art may make some changes and modifications without departing from the spirit and scope of the disclosure. The scope of protection of the disclosure should be defined by the scope of the appended claims.

What is claimed is:

1. An electrode for a two-dimensional semiconductor device, comprising a contact electrode and a metal electrode, wherein the contact electrode, made of a semi-metal alloy, has its Fermi surface adjusted by altering an alloy ratio to generate only gap states within leV or zero on an energy gap when in contact with a two-dimensional semiconductor, thereby reducing a Schottky energy barrier, while maintaining structural stability by creating a space gap slightly smaller than a Van der Waals distance between a semi-metal electrode and the two-dimensional semiconductor to minimize coupling of outer orbital electrons between the metal electrode and the two-dimensional semiconductor.

2. The electrode for the two-dimensional semiconductor device of claim 1, wherein the semi-metal element comprises antimony (Sb), bismuth (Bi), or tin (Sn).

3. The electrode for the two-dimensional semiconductor device of claim 1, wherein the semi-metal alloy is an antimony-bismuth alloy or a bismuth-aluminum alloy.

4. The electrode for the two-dimensional semiconductor device of claim 3, wherein an antimony content in the antimony-bismuth alloy is between 10 a % and 84 a %.

5. The electrode for the two-dimensional semiconductor device of claim 1, wherein the Fermi surface of the semi-metal alloy is matched with the Fermi surface of the n-type or p-type two-dimensional semiconductor to achieve the lowest Schottky energy barrier.

6. The electrode for the two-dimensional semiconductor device of claim 1, wherein the metal electrode comprises platinum (Pt), gold (Au), aluminum (Al), titanium (Ti), or chromium (Cr).

7. A two-dimensional semiconductor device, comprising a substrate, a two-dimensional semiconductor layer formed on the substrate, and a plurality of electrodes, comprising a metal electrode and a contact electrode made of a semi-metal alloy comprising several semi-metal elements or at least one semi-metal element and its alloy, wherein the contact electrode creates a space gap slightly smaller than a Van der Waals distance between a semi-metal electrode and the two-dimensional semiconductor layer, effectively preventing or minimizing coupling of outer orbital electrons between the metal electrode and a two-dimensional semiconductor.

8. The two-dimensional semiconductor device of claim 7, wherein the semi-metal element comprises antimony (Sb), bismuth (Bi), or tin (Sn).

9. The two-dimensional semiconductor device of claim 7, wherein the semi-metal alloy is an antimony-bismuth alloy or a bismuth-aluminum alloy.

10. The two-dimensional semiconductor device of claim 7, wherein the metal electrode comprises platinum (Pt), gold (Au), aluminum (Al), titanium (Ti), or chromium (Cr).

11. The two-dimensional semiconductor device of claim 7, wherein a material of the two-dimensional semiconductor layer comprises tungsten disulfide (WS₂), molybdenum disulfide (MoS₂), tungsten diselenide (WSe₂), molybdenum ditelluride (MoTe₂), tungsten ditelluride (WTe₂), or molybdenum diselenide (MoSe₂).
